(19) United States
(12) Patent Application Publication
(10) Pub. No.: US 2011/0056563 A1
(43) Pub. Date: Mar. 10, 2011

(54) ELECTROLYTE COMPOSITION

(75) Inventor: Mazhar Ali Bari, Dublin (IE)

(73) Assignee: Solarprint Limited, Dublin (IE)

(21) Appl. No.: 12/918,142

(22) PCT Filed: Feb. 19, 2009
(86) PCT No.: PCT/GB2009/000444

§ 371 Date: Nov. 18, 2010

(30) Foreign Application Priority Data
Feb. 19, 2008 (GB) 0803003.3

(51) Int. Cl. H01L 51/46; H01G 9/022

(52) U.S. Cl. 136/263; 252/62.2

(57) ABSTRACT

A method of preparing an electrolyte composition comprising an ionic liquid and carbon particles and/or platinium nanoparticles for use in photoelectric cells, the method comprising comminuting carbon particles and/or platinum nanoparticles in the presence of the ionic liquid.

The present invention relates to a method of preparing an electrolyte composition, an electrolyte composition and its use in photoelectric cells. The photoelectric cells may be dye-sensitised photoelectric cells, and in particular may be dye-sensitised solar cells (DSSC).

Dye-sensitized photoelectric cells are a class of solar cells which were invented by Michael Grätzel et al. They have the advantage of being low cost compared to previously known photoelectric conversion cells.

Dye-sensitized photoelectric cells generally include a transparent conductive electrode substrate which adjoins a working electrode. The working electrode comprises a porous layer of oxide semiconductor particles (such as titanium dioxide) which is sensitised with a photo-sensitising dye. A counter electrode is provided on the opposing side of the working electrode, and between the working electrode and the counter electrode there is an electrolyte solution. In use, dye-sensitized photoelectric cells convert light energy into electricity.

As outlined above, in the original dye-sensitized photoelectric cells, an electrolyte solution is provided between the working electrode and the counter electrode. Traditionally such an electrolyte solution was an oxidation-reduction pair, such as I⁻/I₃⁻ dissolved in organic solvent. However, such systems have disadvantages associated with the high volatility of the organic solvents used. Additionally, the liquid electrolyte solution may leak when it is exposed, for example during manufacture or breakage of the cell.

Attempts have been made to overcome such disadvantages, for example JP 2007-227087 discloses an electrolyte comprising 1 to 50 mass % of a p-type conductive polymer, 5 to 50 mass % of an ionic liquid and from 20 to 85% of a carbon material. Such a composition allows a solid state charge transport layer to be manufactured.

It is an object of the present invention to address at least some of the problems and disadvantages of the prior art. The present invention provides an electrolyte composition which is not liquid, so that the problems associated with leakage are reduced, if not removed. Furthermore, it is advantageous to provide an electrolyte composition that exhibits a high conversion efficiency compared to known electrolyte solutions/compositions. Furthermore, it is advantageous to provide an electrolyte composition that is cheap and cost effective to manufacture and which enables the manufacture of a cheap and efficient dye-sensitized photoelectric cell.

In a first aspect of the present invention there is provided a method of preparing an electrolyte composition comprising an ionic liquid and carbon particles and/or platinum nanoparticles for use in photoelectric cells, the method comprising comminuting carbon particles and/or platinum nanoparticles in the presence of the ionic liquid.

In a second aspect of the present invention there is provided an electrolyte composition as prepared using the method as described herein.

In a third aspect of the present invention there is provided a photoelectric cell (and in particular dye-sensitising photoelectric cells) comprising the electrolyte composition as prepared using the method as described herein.

In a fourth aspect of the present invention there is provided an electrolyte composition consisting of one or more ionic liquids and carbon particles and/or platinum nanoparticles.

In a fifth aspect of the present invention there is provided a photoelectric cell (and in particular dye-sensitising photoelectric cells) comprising the electrolyte composition consisting or comprising of one or more ionic liquids and carbon particles and/or platinum nanoparticles.

The present inventors have surprisingly found that by using the method of the present invention, an electrolyte composition can by prepared which has advantageous physical and photoelectric properties for use in photoelectric cells (and in particular dye-sensitising photoelectric cells). In particular, the method of the present invention involves comminuting carbon particles and/or platinum nanoparticles in the presence of the ionic liquid to form an electrolyte composition.

As used herein the term “comminuting” is used to mean the process of reducing material to a powder by, for example, attrition, impact, crushing, grinding, abrasion, milling or chemical methods. In the present invention as the particles are titurated/comminuted in the presence of an ionic liquid, preferably a paste is formed. The quasi solid-state electrolyte paste is made by the energetic agitation of the components of the electrolyte.

Such a method has the advantage that the particles are substantially evenly distributed throughout the ionic liquid. This reduces the risk of clusters of the particles being present in the electrolyte. The stability and performance of DSSCs have been shown to increase by replacing conventional volatile liquid electrolytes by non-volatile room temperature ionic salts. Typically this results in reduced DSSC efficiency. In the present invention, the incorporation of particles and in particular carbon particles and platinum nanoparticles in the ionic salts not only provides a quasi solid-state paste, but advantageously provides an increase in the conductivity of the system and hence greatly improves the performance of the DSSC.

As used herein the term “paste” is used to mean a thick dispersion of powder in a fluid. The electrolyte in the form of a paste has a reduced flowability compared to a liquid electrolyte. This makes the electrolyte composition safe, durable and easy to handle. It also allows a photoelectric cell manufactured using this electrolyte composition to be amenable to high speed roll-to-roll continuous manufacturing, screen printing, slot-dye coating, flexography, spray pyrolysis deposition and aerosol spray. Moreover, the electrolyte composition may undergo doctor blading or electrodeposition. Such methods may not be possible for prior art compositions which are in a liquid or gel form. Furthermore, photoelectric cells comprising this electrolyte composition exhibit high conversion efficiency.

Each aspect as defined herein may be combined with any other aspect or aspects unless clearly indicated to the contrary. In particular any feature indicated as being preferred or advantageous may be combined with any other feature or features indicated as being preferred or advantageous.

The carbon particles as used herein contain carbon as the main component. Preferably the carbon particles comprise at least 85%, at least 90%, at least 95% or more preferably at least 99% by weight of carbon based on the total weight of the particles. Carbon particles for use in the present invention include carbon nanoparticles, carbon nanotubes, carbon nanofibres, carbon black, graphite, graphene, carbon nanobuds, amorphorus carbon, diamond, bucky paper and mixtures of two or more thereof. Platinum nanoparticles and other suitable metallic nanoparticles may also be used in the present invention. Methods of manufacturing such materials are well-known; alternatively, commercially available materials may be used.

The carbon nanotubes may be single-wall carbon nanotubes (SWCNT) and/or multi-wall carbon nanotubes (MWCNT) having multiple layers (two or more layers). Such materials are known in the art. Preferably the carbon particles include/or are single-wall carbon nanotubes. The present inventors have found that using single-wall carbon nanotubes in the electrolyte compositions of the present invention in photoelectric cells enables particularly high photoelectric conversation rates to be achieved.

In one embodiment of the present invention, the electroyte composition comprises single-wall carbon nanotubes (SWCNT) and multi-wall carbon nanotubes (MWCNT).

In another embodiment of the present invention, the electrolyte composition comprises single-wall carbon nanotubes (SWCNT) and/or multi-wall carbon nanotubes (MWCNT) and graphite. These combinations are particularly advantageous due to the high conductivity of the carbon nanotubes. In this embodiment, preferably the composition comprises from 5 to 95% of single-wall carbon nanotubes (SWCNT) and/or multi-wall carbon nanotubes (MWCNT) and from 95 to 5% of graphite based on the total weight of particles in the electrolyte composition. The composition may comprise from 10 to 80% of single-wall carbon nanotubes (SWCNT) and/or multi-wall carbon nanotubes (MWCNT) and from 90 to 20% of graphite based on the total weight of particles in the electrolyte composition. Preferably, the composition comprises single-wall carbon nanotubes (SWCNT) and graphite. In this embodiment, preferably the composition comprises from 5 to 95% of single-wall carbon nanotubes (SWCNT) and/or multi-wall carbon nanotubes (MWCNT) and from 95 to 5% of graphite based on the total weight of particles and nanoparticles in the electrolyte composition. The composition may comprise from 10 to 80% of single-wall carbon nanotubes (SWCNT) and/or multi-wall carbon nanotubes (MWCNT) and from 90 to 20% of graphite based on the total weight of particles and nanoparticles in the electrolyte composition.

The size of the carbon particles are preferably between 0.5 nm and 10 nm in diameter and between about 10 nm to 1 μm, or up to few cm (for example up to 1 cm, 2 cm, or 3 cm), in length, for example for single-wall carbon nanotubes. Preferably, the single wall carbon nanotubes have a diameter of from 1 to 10 nm. For multi-wall carbon nanotubes, those having a diameter of between about 1 nm and 100 nm and a length of between about 50 nm to 50 μm are preferable. More preferably, the multi-wall carbon nanotubes have a diameter of from 15 to 45 nm. The carbon particles may be carbon nanoparticles, preferably having a diameter of between 0.5 nm and 10 nm and a length or between 10 nm and 1 μm. For carbon fibers, those having a diameter of between about 50 nm and 1 μm and a length of between about 1 μm to 100 μm are preferable. For carbon black, those having a particle diameter of between about 1 nm and 500 nm are preferable.

The electrolyte compositions may further comprise doped or undoped titanium dioxide nanoparticles. The nanoparticles may be nanotubes. In one embodiment titanium dioxide may be coated on to the carbon nanotubes. Methods of coating such particles are well known in the art.

Preferably the particles used in the present invention have a purity of at least 80%, more preferably at least 90%, more preferably still at least 95% or at least 99%. The purity of particles, for example SWCNT, may be measured for example using SEM, Transmission Electron Microscopy, RAMAN and Thermal Gravimetry Analysis(TGA) techniques.

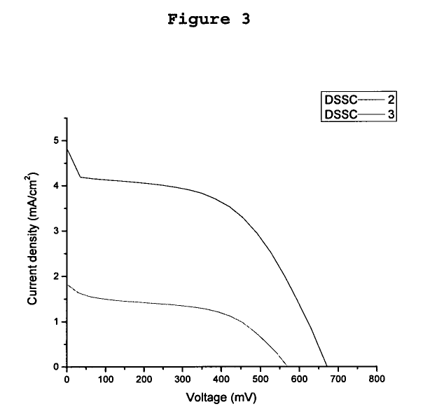

When the particles are single walled carbon nanotubes the inventors have found that it is particularly advantageous for the purity of the single walled carbon nanotubes to be at least 75%, more preferably at least 80%, more preferably at least 90%, more preferably still at least 95% or at least 99%. Addition of non-conducting particles or impurities in the particles, for example in the single wall carbon nanotubes, will reduce conductivity hence reduce the efficiency of the solar cells (see FIG. 3).

Any suitable ionic liquid may be used. The ionic liquid may be selected from 1-hexyl-3-methylimidazolium iodide, 1-propyl-3-methylimidazolium iodide, 1-hexyl-2,3-dimethylimidazolium iodide, 1-propyl-2,3-dimethylimidazolium iodide, 1-ethyl-3-methylimidazolium tricyanomethanide, allymethylimidiazolium iodide, dimethylimidazolium iodide, 3-ethyl-1-methylimidazolium iodide and mixtures of two or more thereof. Preferably the ionic liquid is selected from 1-hexyl-3-methylimidazolium iodide, 1-propyl-3-methylimidazolium iodide, 1-hexyl-2,3-dimethylimidazolium iodide, 1-propyl-2,3-dimethylimidazolium iodide and mixtures of two or more thereof.

Most preferably the ionic liquid is 1-hexyl-3-methylimidazolium iodide. Surprisingly, the present inventors have found that substantially higher photoelectric conversation rates in dye sensitised photoelectric cells comprising the electrolyte composition of the present invention are observed if the ionic liquid is/or comprises 1-hexyl-3-methylimidazolium iodide or 1-propyl-3-methylimidazolium iodide. This effect is enhanced if the carbon particles are single walled carbon nanotubes, and graphite.

The size of the platinum nanoparticles are preferably between 0.5 nm and 10 nm in diameter and between about 10 nm to 1 μm in length. More preferably, the platinum nanoparticles are between 1 nm and 5 nm in diameter and between about 10 nm to 1 μm in length.

Preferably the platinum nanoparticles are in the form of nanoparticles of platinum. Preferably they are not colloids of platinum.

The platinum nanoparticles may be present in the form of titanium dioxide nanotubes loaded with platinum nanoparticles. Methods of making titanium dioxide nanotubes are well known in the art. Similarly, methods of loaded said nanotubes with nanoparticles are known (for example from photo-catalysis and environmental catalysis, fuel cells & battery applications).

In addition to the carbon particles and/or platinum nanoparticles used in the present invention the electrolyte composition may comprise doped or undoped titanium dioxide nanoparticles. The titanium dioxide nanoparticles may be nanotubes. Methods of doping titanium dioxide are well known in the art, for example in US 2006/0210798. The size of the titanium dioxide nanoparticles are preferably between 1 nm and 50 nm in diameter and between about 10 nm to 1 μm in length. More preferably, the titanium dioxide nanoparticles are between 0.5 nm and 10 nm in diameter and between about 10 nm to 1 μm in length.

Preferably the electrolyte composition comprises at least 5%, at least 10%, at least 30% by weight of particles based on the total weight of the electrolyte composition. More preferably still, the electrolyte composition comprises at least 15% by weight of particles based on the total weight of the electrolyte composition. This may be particularly advantageous when the ionic liquid is 1-hexyl-3-methylimidazolium iodide or 1-propyl-3-methylimidazolium iodide

Preferably the electrolyte composition comprises at least 5%, at least 10%, at least 30%, or at least 50% by weight of carbon particles based on the total weight of the electrolyte composition. More preferably still, the electrolyte composition comprises at least 15% by weight of carbon particles based on the total weight of the electrolyte composition. This may be particularly advantageous when the ionic liquid is 1-hexyl-3-methylimidazolium iodide or 1-propyl-3-methylimidazolium iodide.

Preferably when the electrolyte composition comprises single walled and/or multi walled carbon nanotubes it comprises from 0.01 to 50% or from 0.01 to 30%, more preferably from 0.1 to 25%, more preferably still from 5 to 15% by weight of single walled and/or multi walled carbon nanotubes based on the total weight of the electrolyte composition. SWCNTs may be conducting or semi-conducting depending on the nature of their chirality. Preferably they have a p-type characteristic which provides higher efficiency in DSSCs. Advantageously, SWCNTs also have very low density. Although MWCNTs typically do not show the p-type characteristic, one advantage of MWCNT use is that all the MWCNTs in a given mass are conducting.

Preferably when the electrolyte composition comprises carbon nanofibers it comprises from 0.01 to 50%, more preferably from 5 to 30%, more preferably still from 10 to 20% by weight of carbon nanofibers based on the total weight of the electrolyte composition.

Preferably when the electrolyte composition comprises graphite it comprises from 5 to 80%, more preferably from 15 to 60%, more preferably still from 30 to 50% by weight of graphite based on the total weight of the electrolyte composition.

In another embodiment of the present invention, the electrolyte composition comprises less than 5%, less than 10%, less than 30% by weight of carbon particles based on the total weight of the electrolyte composition. More preferably still, the electrolyte composition comprises less than 15% by weight of carbon particles based on the total weight of the electrolyte composition.

Preferably when the electrolyte composition comprises platinum nanoparticles it comprises from 0.01 to 50%, more preferably from 0.1 to 25%, more preferably still from 5 to 15% by weight of platinum nanoparticles based on the total weight of the electrolyte composition.

Preferably when the electrolyte composition comprises doped or undoped TiO₂ nanoparticles it comprises from 0.5 to 20%, more preferably from 1 to 10%, more preferably still from 2 to 5%, by weight of doped or undoped TiO₂ nanoparticles based on the total weight of the electrolyte composition.

In a preferred embodiment the electrolyte composition comprises at least 50% by weight of an ionic liquid, and preferably of 1-hexyl-3-methylimidazolium iodide based on the total weight of the electrolyte composition. More preferably, the electrolyte composition comprises at least 75% by weight or at least 80% of ionic liquid, which may be, or comprise 1-hexyl-3-methylimidazolium iodide, based on the total weight of the electrolyte composition.

Typically the electrolyte composition is in the form of a viscous paste. Preferably, the electrolyte of the present invention has a thicker consistency than a gel. Preferably the electrolyte composition of the present invention has a viscosity in the range of from 70 to 10,000 cP (0.07 Pa·s to 10 Pa·s). More preferably the viscosity is in the range of from 800 to 10,000 cP (0.8 to 10 Pa·s). Viscosity may be measured using a Brookfield DVIII Rheometer. The viscosity is measured as function of temperature (0-50° C.) and shear rate. Typically, viscosity may be measured at a temperature of 25° C. and a shear rate of from 0 to 200 s⁻¹, for example 100 s⁻¹).

Prior art electrolyte compositions which are gels have the disadvantage that the gels become less viscous and more liquid-like if the solar cell in which they are contained is shaken. This increases the risk of leakage of the electrolyte from the cell. The same phenomena may occur with an increase in temperature.

Using the electrolyte composition of the present invention, the inventors have manufactured dye sensitized photoelectric cells having greater than two times the power conversion efficiency than dye sensitized photoelectric cells known in the prior art. Power conversion is measured using Keithley 2400 and white LED as light source.

The electrolyte composition may comprise a polymer, which may be an organic polymer. Preferably, the electrolyte composition comprises less 15%, less than 10%, less than 5% or less than 1% by weight of a polymer, which may be an organic polymer, based on the total weight of the composition.

The electrolyte composition may comprise a solvent other than an ionic liquid. Preferably, the electrolyte composition comprises less 15%, less than 10%, less than 5% or less than 1% by weight of a solvent other than an ionic liquid based on the total weight of the composition.

Preferably the electrolyte composition of the present invention does not comprise a p-type polymer.

Preferably, the electrolyte composition does not comprise a polymer or an organic polymer.

Preferably, the electrolyte composition does not comprise a solvent other than one or more ionic liquid(s).

Preferably, the electrolyte composition does not comprise an organic polymer or solvent other than one or more ionic liquid(s). It has surprisingly been found that electrolyte compositions having high conductivity in a paste like form maybe prepared without the addition of such additional solvents, or polymers. Advantageously, this makes manufacture of the electrolyte composition cheaper and easier.

In one embodiment of the present invention, the electrolyte composition comprises at least two different ionic liquids. The electrolyte composition may, for example, comprise 1-propyl-3-methylimidazolium iodide (PMII) and 1-ethyl-3-methylimidazolium tricyanomethanide (EMITCM). In another embodiment the electrolyte composition comprises at least three different ionic liquids. In a further embodiment the electrolyte composition comprises four or more different ionic liquids.

The present inventors have found that combining more than one ionic liquid (ionic salt) allows unique eutectic mixes to be prepared which have superior conductivity. For example, the electrolyte composition of the present invention may comprise Allymethylimidiazolium iodide (AMII),

Dimethylimidazolium iodide (DMII) and 3-ethyl-1-methylimidazolium iodide (EMII).

In one embodiment, the present invention provides an electrolyte composition consisting or comprising of one or more ionic liquids and carbon particles and/or platinum nanoparticles.

The electrolyte composition may consist or comprise of at least one ionic liquid selected from 1-hexyl-3-methylimidazolium iodide, 1-propyl-3-methylimidazolium iodide, 1-hexyl-2,3-dimethylimidazolium iodide, 1-propyl-2,3-dimethylimidazolium iodide, 1-ethyl-3-methylimidazolium tricyanomethanide, allymethylimidiazolium iodide, dimethylimidazolium iodide, 3-ethyl-1-methylimidazolium iodide and mixtures of two or more thereof, carbon particles and/or platinum nanoparticles, optionally doped or un-doped titanium nanoparticles and/or optionally doped or un-doped titanium nanotubes.

The electrolyte composition may consist or comprise an ionic liquid selected from 1-hexyl-3-methylimidazolium iodide and/or 1-propyl-3-methylimidazolium iodide, carbon particles and/or platinum nanoparticles, optionally doped or un-doped titanium nanoparticles and/or optionally doped or un-doped titanium nanotubes.

The present invention will now be described further, by way of example only, with reference to the following figures, in which:

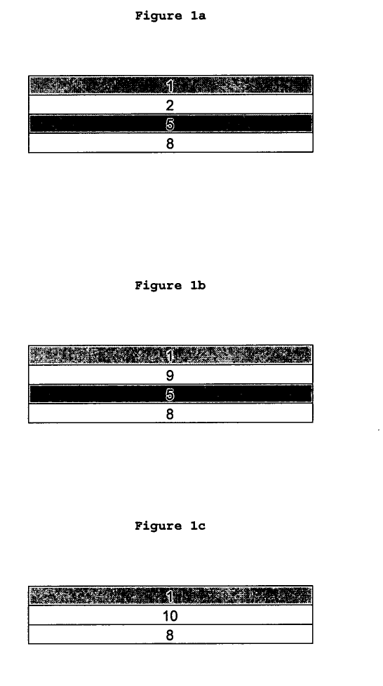

FIG. 1a: illustrates a diagrammatic cross-sectional view of a dye-sensitised photoelectric cell comprising the electrolyte composition as described herein; and

FIG. 1b: illustrates a diagrammatic cross-sectional view of a photoelectric cell of one embodiment of the present invention comprising the electrolyte composition as described herein; and

FIG. 1c: illustrates a diagrammatic cross-sectional view of a photoelectric cell of a further embodiment of the present invention comprising the electrolyte composition as described herein; and

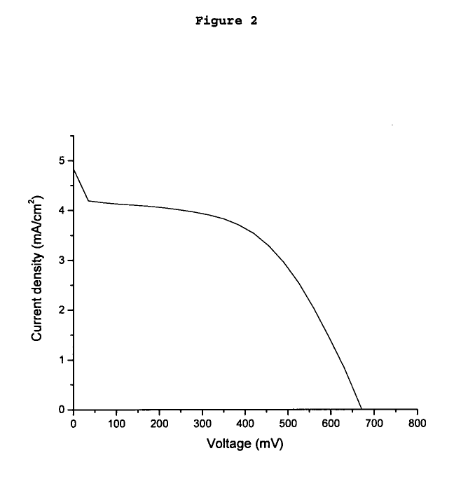

FIG. 2: Shows the Current Density vs Voltage (J-V) characteristic of the SWCNT-based DSSC. The J-V characteristic of the SWCNT-cell showed a short-circuit photocurrent density (J_{sc}) of 4.8 mA/cm² and an open-circuit voltage (V_{oc}) between 0.68V. The overall power conversion efficiency is between 4.5% with a fill factor of 0.52.

FIG. 3: is a graph showing the influence of the purity of SWCNT. For DSSC3 the SWCNT purity is less than 80%. The cell efficiency is 3.16%, FF is 0.43. Cell DSSC 2 uses SWCNT with purity of greater than 80%. The cell efficiency is 40% higher (4.5%), with a FF of 0.52.

The present invention may be further understood with reference to the diagrammatic cross-sectional views of photoelectric cells shown in FIGS. 1a, 1b and 1c.

FIG. 1a shows an embodiment of the present invention. FIG. 1a shows a dye sensitised photoelectric (solar) cell comprising: a transparent conductive electrode 1; a working electrode 2, which comprises semiconductor 3 sensitised with a dye 4; a electrolyte composition of the present invention 5 which contains carbon particles 6 and an ionic liquid 7 (preferably 1-hexyl-3-methylimidazolium iodide); and a counter transparent electrode 8.

Each component of this diagram will be discussed in more detail below.

The transparent conductive electrode 1 preferably comprises a transparent conductive substrate on a transparent substrate.

The transparent conductive substrate can be formed, for example, from metal (for example, platinum, gold, silver, copper, aluminium, indium), carbon, conductive metallic oxide (for example, the tin oxide, zinc oxide), or composite metal oxide (for example, an indium tin oxide, an indium zinc oxide). Preferably the transparent conductive substrate comprises an indium tin oxidation substrate (ITO), a zinc oxide, and/or an indium zinc oxide (IZO). Most preferably, it comprises indium tin oxidation substrate (ITO). The electrode may be comprised of a carbon nanotube (nanobud)and transparent polymer. Moreover the transparent electrode may comprise a semitransparent nanomesh copper electrode on a polyethylene terephthalate PET or PEN substrate using metal which may be formed for example by metal transfer from a polydimethylsiloxane PDMS stamp and/or nanoimprint lithography.

The transparent substrate may be, for example, a glass plate or a plastic film. A plastic film with flexibility is more preferred than a glass plate. The plastic material used for a substrate preferably has a high transparency, is color-free, has a high heat resistance, excels in chemical resistance, and is low cost. Examples of suitable plastic materials include but are not limited to polyethylene terephthalate (PET), polyethylenenaphthalate (PEN), syndiotactic polystyrene (SPS), polyphenylene sulfide (PPS), polycarbonate (PC), polyarylate (Par), polysulfone (PSF), polyester sulfone (PES), polyether imide (PEI), and polyimide (PI). Polyethylene terephthalate (PET) and polyethylenenaphthalate (PEN) are preferred.

In FIG. 1 a the working electrode comprises a semiconductor 3 which is sensitised with a dye/sensitiser 4.

The semiconductor 3 preferably comprises an n type inorganic semiconductor. Suitable materials include, but are not limited to, TiO₂, TiSrO₃, ZnO, Nb₂O₃, SnO₂, WO₃, Si, CdS, CdSe, V₂O₅, ZnS, ZnSe, SnSe, KTaO₃, FeS₂, and PbS are included. Of these, TiO₂, SnO, SnO₂, WO₃, and Nb₂O₃ are preferred. Preferably, the semicondutor includes titanium oxide, a zinc oxide, tin oxide, most preferably it is titanium dioxide. Alternatively, any other conductive metals oxide with semiconductor properties and a large energy gap (band gap) between the valency band and the conductivity ban can be used.

The semi-conductor is sensitised with a dye/or senitiser 4. Suitable dyes are well known, and include ruthenium complexes or iron complexes containing a ligand having bipyridine structures, terpyridine structures, and the like. The dye can be selected according to the application and the material used for the oxide semiconductor porous film. Examples of suitable chromophores, i.e., sensitizers, are complexes of transition metals of the type metal (L₃), (L₂) of ruthenium and osmium (e.g., ruthenium tris (2,2′bipyridyl-4,4′dicarboxylate), ruthenium cis-diaqua bipyridyl complexes, such as ruthenium cis diaqua bis (2,2′bipyridyl-4,4′dicarboxylate) and porphyrins (e.g. zinc tetra (4-carboxyphenyl) porphyrin) and cyanides (e.g. iron-hexacyanide complexes) and phthalocyanines. Suitable dyes include near IR dyes, which are known in the art and mixtures of dyes.

The electrolyte composition of the present invention 5 is as described herein and contains carbon particles and/or platinum nanoparticles 6 and an ionic liquid 7 (which is preferably 1-hexyl-3-methylimidazolium iodide or 1-propyl-3-methylimidazolium iodide.).

The working electrode 2 comprising the semiconductor 3 sensitised with the dye may form a layer adjoined to a layer of the electrolyte composition 5. In another embodiment, the electrolyte composition 5 may be dispersed in the working electrode 2 (semiconductor). The electrolyte composition 5 may be substantially evenly distributed throughout the semiconductor. It may be distributed in only a portion of the semiconductor.

The counter electrode 8 may be one obtained by forming a thin film made of a conductive oxide semiconductor, such as ITO, FTO, or the like, on a substrate made of a non-conductive material, such as a glass, or plastic such as (PET, PEN) or one obtained by forming an electrode by evaporating or applying a conductive material, such as gold, platinum, a carbon-based material, and the like, on a substrate. Moreover the electrode may be comprised of a carbon nanotube and transparent polymer. Furthermore, the counter electrode 8 may be one obtained by forming a layer of platinum, carbon, or the like, on a thin film of a conductive oxide semiconductor, such as ITO, FTO, or the like.

It is advantageous to ensure that there is a good insulating layer between the working electrode and the counter electrode. This prevents, or reduces the risk of shorting occurring. Preferably an insulating layer is provided on the working electrode. The insulating layer may be provided on the working electrode by painting or screen painting a polymer, such as an acrylic resin, polyamide, or an alkyl resin, with, or without plasticizers onto the electrode. Such a layer adheres easier to the electrode and has good film flexibility.

Preferably the insulating layer for the working electrode comprises a solvent (which may be for example ethyl or butyl acetate), cellulose nitrate, and optionally one or more of a plasticizer, silicate, resin and pigment.

For long term stability it is advantageous for photoelectric cells to be dye-free and electrolyte free. This allows a dry solid state photoelectric cell to be produced. The present inventors have found that such a cell may be produced by using the electrolyte composition of the present invention, and by replacing the dye-sensitised semiconductor, which typically comprises TiO₂ of traditional dye-sensitised photoelectric cells, with CeO₂ nanoparticles which are not dye-sensitised. This makes it possible to produce a photoelectric cell with reduced manufacturing costs compared to known photoelectric cells. Furthermore, it avoids the drying time (typically 12 hours) required in the manufacture of traditional dye-sensitised photoelectric cells. These “dry” photoelectric cells also have increased durability.

CeO₂ is not generally considered a semiconductor nor a photoactive material. However, it has been found that non-doped and rare-earth-doped CeO₂ nanoparticles exhibit a photovoltaic response derived directly from the nanometric structure of the constituent particles. Usually large-particle-size CeO₂ do not possess a photovoltaic response. Typically in order to observe a photovoltaic affect the CeO₂ nanoparticles must be in the range of from 3 to 10 nm, and more preferably from 5 to 7 nm.

The absorption spectrum of CeO₂ nanoparticles is shifted about 80 nm compared to the absorption spectrum of TiO₂. This results in the absorption spectrum having a better response in the visible region of the solar spectrum.

The Cerium oxides may be undoped or doped by rare earth cations, pentavalent cations, and tetravalent cations. Examples of suitable doping materials include, but are not limited to, La³⁺, Pr³⁺, Pr⁴⁺, Tb³⁺, Nb⁵⁺, Zr⁴⁺and mixtures of two or more thereof.

FIG. 1b shows one embodiment of the present invention comprising: a transparent conductive electrode 1; a working electrode, which comprises a layer of a composition comprising CeO₂ 9 adjoined to a layer of an electrolyte composition of the present invention 5 which contains carbon particles and/or platinum nanoparticles 6 and an ionic liquid 7 (preferably 1-hexyl-3-methylimidazolium iodide); and a counter transparent electrode 8.

FIG. 1c shows further embodiment of the present invention comprising: a transparent conductive electrode 1; a working electrode, which comprises a composition comprising CeO₂ 9 and an electrolyte composition of the present invention 5 which contains carbon particles and/or platinum nanoparticles 6 and an ionic liquid 7 (preferably 1-hexyl-3-methylimidazolium iodide); and a counter transparent electrode 8.

The electrolyte composition 5 may form a layer between the counter electrode and the working electrode which comprises a composition comprising CeO₂ 9 (see FIG. 1b). The electrolyte composition 5 may be dispersed in the working electrode which comprises a composition comprising CeO₂ 9. The electrolyte composition 5 may be substantially evenly distributed throughout the working electrode which comprises a composition comprising CeO₂ 9. It may be distributed in only a portion of the working electrode 9.

In one embodiment of the present invention there is provided an photoelectric cell comprising the electrolyte composition as defined herein. Preferably, the photoelectric cell is a dye sensitized photoelectric cell comprising a transparent electrode (1); a working electrode (2) comprising a semiconductor (3) sensitised with a dye (4); a electrolyte composition (5) as defined herein; and a counter electrode (8). Preferably the semiconductor comprises TiO₂. Preferably working electrode comprises a composition comprising CeO₂ (9). More preferably, the working electrode (9) comprises a layer of a composition comprising CeO₂ which is adjoined to a layer of the electrolyte composition as defined herein. The electrolyte composition may be dispersed within the composition comprising CeO₂. The composition comprising CeO₂ may comprise nanoparticles of CeO₂. The CeO₂ may be doped with a rare earth metal.

Two main geometries of DSSC are known, those having front illumination (as shown in the Figures) and those having rear illumination. It will be understood that the electrolyte composition as described herein may be used in DSSCs having either front or rear illumination. Moreover the electrolyte composition as described herein is ideally suited to use in tandem cell designs.

In one embodiment the present invention provides a method of preparing an electrolyte composition comprising an ionic liquid and carbon particles and/or platinum nanoparticles for use in photoelectric cells, the method comprising comminuting carbon particles and/or platinum nanoparticles in the presence of the ionic liquid. The electrolyte composition may comprise one or more ionic liquids.

Preferably, the electrolyte composition does not comprise a solvent or a polymer other than the ionic liquid(s).

The present invention will be further illustrated with reference to the following non-limiting Example.

### EXAMPLE 1

Commercial FTO coated glass with a TiO₂ thickness of 15-20 μm was heated at 450° C. for 30 mins before being soaked in ruthenium complex dye (N719) (from Solaronix). The SWCNT-based conductive mixture was prepared by titurating 40 mg of solid single wall carbon nanotube (SWCNT) powder (Carbon Nanotechnologies, Inc or Unidym Inc) in the presence of 300 mg of an ionic liquid 1-hexyl-3-methylimidazolium iodide (HM11 from Solaronix) on an agate/glass mortar. The resulting mixture is a viscous black paste and contains no volatile elements. A 10-50 μm thick layer of this CNT paste is then applied onto the dye-sensitised TiO₂ layer before being sandwiched by the glass counter electrode. In our process, no Pt catalyst is required and the whole fabrication procedure is carried out in normal laboratory conditions. Photocurrent density-voltage measurements were obtained using a Keithley 2400 source meter with a LED lamp with light irradiation of 150 mW/cm².

FIG. 1 shows the Current Density vs Voltage (J-V) characteristic of the SWCNT-based glass DSSC. The J-V characteristic of the SWCNT-cell showed a short-circuit photocurrent density (J_{sc}) of 4.8 mA/cm² and an open-circuit voltage (V_{oc}) between 0.68V. The overall power conversion efficiency was between 4.5% with a fill factor of 0.52. Devices sizes ranged from 5×5 mm-10×10 mm.

### EXAMPLE 2

A similar experiment was carried out using the same method as that described in Example 1, but by using a SWCNT and graphite composite.

### EXAMPLE 3

The solar cell was prepared by suspending 10 mg of doped ceria in acetylacetone, and depositing the suspension in a 1×1 cm² square defined by adhesive tape on a transparent indium-tin oxide electrode. After calcining at 300° C. for 2 h, a few drops of water solution containing 0.5 M LiI and 0.05 M I₂ were added.

The CeO₂ nanomaterials were obtained from:
Advanced Material Resources (Europe) LTD; and
M.K. IMPEX CANADA

The CeO₂ particles are made by conventional sol-gel process. The purity of CeO₂ is over 95%.

1. A method of preparing an electrolyte composition comprising an ionic liquid and carbon particles and/or platinum nanoparticles for use in photoelectric cells, the method comprising comminuting carbon particles and/or platinum nanoparticles in the presence of the ionic liquid, and thereby forming a paste.

2. A method according to claim 1 wherein the electrolyte composition comprises more than 10% by weight of carbon particles and/or platinum nanoparticles based on the total weight of the electrolyte composition.

3. A method according to claim 2 wherein the electrolyte composition comprises more than 15% by weight of carbon particles and/or platinum nanoparticles based on the total weight of the electrolyte composition.

4. A method according to claim 1 wherein the electrolyte composition comprises less than 5% by weight of a polymer or a solvent other than the ionic liquid based on the total weight of the electrolyte composition.

5. A method according to claim 1 wherein the carbon particles are selected from carbon nanoparticles, carbon nanotubes, carbon nanofibres, carbon black, graphite, graphene, carbon nanobuds, amorphorus carbon, diamond, bucky paper and mixtures of two or more thereof.

6. A method according to claim 5 wherein the carbon nanotubes are single walled carbon nanotubes.

7. A method according to claim 5 wherein the carbon nanotubes are multi-walled carbon nanotubes.

8. A method according to claim 1 wherein the electrolyte composition further comprises doped or undoped TiO₂ nanoparticles, and/or doped or undoped TiO₂ nanotubes.

9. A method according to claim 1 wherein the ionic liquid is selected from 1-hexyl-3-methylimidazolium iodide, 1-propyl-3-methylimidazolium iodide, 1-hexyl-2,3 - dimethylimidazo lium iodide, 1-propyl-2,3 -dimethylimidazo lium iodide, 1-ethyl-3 -methylimid azo lium tricyanomethanide, allymethylimidiazolium iodide, dimethylimidazolium iodide, 3-ethyl-1-methylimidazolium iodide and mixtures of two or more thereof.

10. A method according to claim 9 wherein the ionic liquid is 1-hexyl-3-methylimidazolium iodide.

11. A method according to claim 1 wherein the electrolyte composition comprises at least 80% by weight of the ionic liquid based on the total weight of the electrolyte composition.

12. An electrolyte composition which is obtainable by a method comprising comminuting carbon particles and/or platinum nanoparticles in the presence of an ionic liquid, wherein the electrolyte composition is in the form of a paste.

13. A photoelectric cell comprising an electrolyte composition which is obtainable by a method comprising comminuting carbon particles and/or platinum nanoparticles in the presence of an ionic liquid, wherein the electrolyte composition is in the form of a paste.

14. A photoelectric cell according to claim 13 wherein the cell is a dye sensitized photoelectric cell comprising a working electrode comprising a semiconductor sensitised with a dye; the electrolyte composition; and a counter electrode, wherein the working electrode or the counter electrode is a transparent electrode.

15. A dye sensitized photoelectric cell according to claim 14 wherein the semiconductor comprises TiO₂.

16. An electrolyte composition comprising one or more ionic liquids and carbon particles and/or platinum nanoparticles, optionally, doped or undoped TiO₂ nanoparticles and optionally, doped or undoped TiO₂ nanotubes, wherein the electrolyte composition is a paste.

17. An electrolyte composition according to claim 16 wherein the one or more ionic liquids are selected from 1-hexyl-3-methylimidazolium iodide, 1-propyl-3-methylimidazolium iodide, 1-hexyl-2,3-dimethylimidazolium iodide, 1-propyl-2,3-dimethylimidazolium iodide, 1-ethyl-3-methylimidazolium tricyanomethanide, allymethylimidiazolium iodide, dimethylimidazolium iodide, 3-ethyl-1-methylimidazolium iodide and mixtures of two or more thereof

18. An electrolyte composition according to claim 17 wherein the one or more ionic liquids are selected from 1-hexyl-3-methylimidazolium iodide and 1-propyl-3-methylimidazolium iodide and mixtures thereof.

19. An electrolyte composition according to claim 16 wherein the carbon particles are selected from carbon nanoparticles, carbon nanotubes, carbon nanofibres, carbon black, graphite, graphene, carbon nanobuds, amorphorus carbon, diamond, bucky paper and mixtures of two or more thereof.

20. An electrolyte composition according to claim 19 wherein the carbon nanotubes are single walled carbon nanotubes.

21. An electrolyte composition according to claim 19 wherein the carbon nanotubes are multi-walled carbon nanotubes.

22. An electrolyte composition according to claim 16 wherein the composition comprises more than 10% by weight of carbon particles and/or platinum nanoparticles based on the total weight of the electrolyte composition.

23. An electrolyte composition according to claim 22 wherein the composition comprises at least 15% by weight of carbon particles and/or platinum nanoparticles based on the total weight of the electrolyte composition.

24. An electrolyte composition according to claim 16 wherein the composition comprises at least 50% by weight of the one or more ionic liquids based on the total weight of the electrolyte composition.

25. An electrolyte composition according to claim 24 wherein the composition comprises at least 75% by weight of the one or more ionic liquids based on the total weight of the electrolyte composition.

26. An electrolyte composition according to claim 16, wherein the composition comprises carbon nanotubes coated with titanium dioxide.

27. A photoelectric cell comprising an electrolyte composition comprising one or more ionic liquids and carbon particles and/or platinum nanoparticles, optionally, doped or undoped TiO₂ nanoparticles and optionally, doped or undoped TiO₂ nanotubes, wherein the electrolyte composition is a paste.

28. A photoelectric cell according to claim 27 wherein the cell is a dye sensitised photoelectric cell comprising a working electrode comprising a semiconductor sensitised with a dye, the electrolyte composition, and a counter electrode, wherein the working electrode or the counter electrode is a transparent electrode.

29. A dye sensitized photoelectric cell according to claim 28 wherein the semiconductor comprises TiO₂.

30. An electrolyte composition according to claim 12 wherein the electrolyte composition has a viscosity of from 70 to 10,000 cP (0.07 Pa·s to 10 Pa·s).

31. An electrolyte composition according to claim 30 wherein the electrolyte composition has a viscosity of from 800 to 10,000 cP (0.8 Pa·s to 10 Pa·s).

32. An electrolyte composition according to claim 16 wherein the electrolyte composition has a viscosity of from 70 to 10,000 cP (0.07 Pa·s to 10 Pa·s).

33. An electrolyte composition according to claim 32 wherein the electrolyte composition has a viscosity of from 800 to 10,000 cP (0.8 Pa·s to 10 Pa·s).
